(19) United States
(12) Patent Application Publication
(10) Pub. No.: US 2016/0020370 A1
(43) Pub. Date: Jan. 21, 2016

(54) THIN FILM WITH MULTILAYER DIELECTRIC COATINGS FOR LIGHT EMITTING DIODE (LED) LEAD FRAME AND CHIP-ON-BOARD (COB) SUBSTRATE REFLECTOR

(71) Applicant: GE Lighting Solutions, LLC, East Cleveland, OH (US)

(72) Inventors: Dengke Cai, Willoughby, OH (US); Cherian Jacob, Brecksville, OH (US); Mark J. Mayer, Sagamore Hills, OH (US); Koushik Saha, Brunswick, OH (US); Xiaomei Lou, Solon, OH (US); Gabriel Michael Smith, East Cleveland, OH (US); Benjamin James Ward, Beachwood, OH (US)

(21) Appl. No.: 14/336,532

(22) Filed: Jul. 21, 2014

(51) Int. Cl. H01L 33/60; H01L 33/22; H01L 33/62

(52) U.S. Cl. CPC H01L 33/60; H01L 33/62; H01L 33/22; H01L 2933/0058; H01L 2933/0033; H01L 2933/0066

(57) ABSTRACT

A light emitting diode (LED) package according to various embodiments can include a metal substrate having a surface roughness. A thin film coated reflector is applied to the metal substrate. At least one light emitting diode (LED) chip is mounted above at least a portion of the metal substrate.

### I. TECHNICAL FIELD

The present invention relates generally to light emitting diode (LED) reflectors. More particularly, the present invention relates to reflectors for use with lead-frame type and chip-on-board (COB) LED packages.

### II. BACKGROUND

Chip-on-board (COB) is an emerging technology of LED packaging for LED light fixtures. Typically, numerous LED chips are packaged together as an LED array to form a single lighting module. When the light is illuminated, it appears as a lighting panel. The closeness of the single LED elements evokes the impression of one common light source—just as a conventional light source.

Some conventional LEDs are fabricated using a metal lead frame (also referred to as “leadframe”). Such an LED is generally fabricated into a package structure having an LED chip mounted thereon, and is commonly referred to as an “LED package.” The LED package includes a lead frame for applying a current to an LED chip, and a housing for supporting the lead frame.

Reflective coating or films are often used in lighting applications, such as LED packages. Reflective coatings or films have been used to selectively reflect or transmit light radiation from various portions of the electromagnetic radiation spectrum, such as ultraviolet, visible, and/or infrared radiation. For instance, reflective coatings are commonly used in the lamp industry to coat reflectors and lamp envelopes. One application in which reflective coatings are useful is to improve the illumination efficiency, or efficacy, of lamps by reflecting infrared energy emitted by a filament, or arc, toward the filament or arc while transmitting visible light of the electromagnetic spectrum emitted by the light source. This decreases the amount of electrical energy necessary for the light source to maintain its operating temperature. Another application of reflective coatings is to improve the efficacy of luminaires by reflecting the visible light from the lamp from a high-reflectance coating on the surface of the luminaire to redirect the light into the intended application space.

Some reflectors include a coating of thin films, such as polymeric or dielectric layers. The latter type can be referred to as a dielectric mirrors, or Bragg reflectors. A related term is a dichroic stack, mirror, or reflector.

Conventional dielectric optical stack reflectors are designed for reflecting optimally only light impinging on the reflector within a limited range of incident angles. An example range is centered about forty-five degrees (45°), such as a range of 40° to 50°. Especially with multi-component light sources, such as LED arrays or clusters within a single lighting apparatus, though, light rays can arrive at intra-apparatus reflectors at a wide variety of incident angles.

While conventional lighting systems are designed so that some reflectors, or portions of a reflector, receive light arriving within the optimal range, other reflectors or portions receive light at angles outside of the optimal range. Incident angles outside of the optimal angles can approach 0° on the low end and 90° on the other. Rays arriving outside of the optimal range reflect with an undesirable shift in color, and less-than-desirable intensity.

Some LED manufacturers have explored using silver metalizing to improve reflectivity in LED packages. Silver, however, has several shortcomings. For example, many existing LED lead frame reflectors and COB type package reflectors are mainly silver (Ag) coated with protective coating on ceramic or metal substrates. In such conventional technology, it is necessary to utilize an organic based top coating to protect Ag from oxidation due to humidity, oxygen dioxide (O₂) and some outgas produced from coating specific wavelength-converting material, such as phosphor, and the surrounding environment.

Thus, there remains a need for a lighting system and method that provides the combined benefits of improved reflectivity produced by a thin film coating applied within a COB LED lead frame package. There also remains a need for a COB LED, which is well proven to exhibit perfect temperature and humidity stability, and outgas resistance. A further need exists to provide a reflector, which does not require an organic based top coating to protect Ag from oxidation due to humidity, O₂ and outgas produced due to phosphors and the environment.

A continuing need exists for a reflective coating having a broad high reflectivity for use, especially, in a lamp or other lighting devices. There also remains a need for an improved efficiency COB LED light fixture with a reflector having over 95% reflectance at a nominal incident angle.

### III. SUMMARY OF THE EMBODIMENTS

A light emitting diode (LED) package according to various exemplary embodiments can include a metal substrate having a surface roughness. A thin film coated reflector is applied to at least a portion of the metal substrate. At least one light emitting diode (LED) chip is mounted above at least a portion of the metal substrate.

A method for producing a light emitting diode (LED) package according to various exemplary embodiments can include forming a lead frame by using a metal substrate having a surface roughness; applying a thin film coated reflector to at least a portion of the metal substrate; and mounting at least one light emitting diode (LED) chip above at least a portion of the metal substrate.

Further features and advantages, as well as the structure and operation of various embodiments, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### IV. BRIEF DESCRIPTION OF THE DRAWINGS

Exemplary embodiments may take form in various components and arrangements of components. Exemplary embodiments are illustrated in the accompanying drawings, throughout which like reference numerals may indicate corresponding or similar parts in the various figures. The drawings are only for purposes of illustrating preferred embodiments and are not to be construed as limiting the invention. Given the following enabling description of the drawings, the novel aspects of the present invention should become evident to a person of ordinary skill in the art.

FIG. 1 is an illustration of an LED package in accordance with embodiments of the present invention.

FIG. 2 is an illustration of a thin film layer formed in accordance with the embodiments of the present invention.

FIG. 3 is a flow diagram of a method for preparing an LED package in accordance with the present invention.

### V. DETAILED DESCRIPTION OF THE EMBODIMENTS

While exemplary embodiments are described herein with illustrative embodiments for particular applications, it should be understood that the invention is not limited thereto. Those skilled in the art with access to the teachings provided herein will recognize additional modifications, applications, and embodiments within the scope thereof and additional fields in which the multi-reflector design described herein would be of significant utility.

In various embodiments, the LED reflector described herein may include a metal substrate. In various embodiments, the metal substrate is a highly conductive metal substrate. For example, the highly semi-conductive metal substrate can be made of a material selected from at least one of the group including aluminum, copper, steel or any metal alloy combination with a thermal conductivity over 10 W/mK.

In various embodiments, the metal substrate can be produced having a particular surface roughness. In various embodiments, a coating may be applied to the surface of the roughened metal substrate to provide a smooth surface. The smoothing technology employed to smooth the surface of the metal substrate may include, for example, anodizing, chemically etching, or other plating technology coating overlaying a metal substrate.

In various embodiments, the system and method is directed towards a LED package. Thus, in various embodiments, an LED package thin film coated reflector with a metal substrate is provided. The thin film reflector may include a multi-layer thin-film layer.

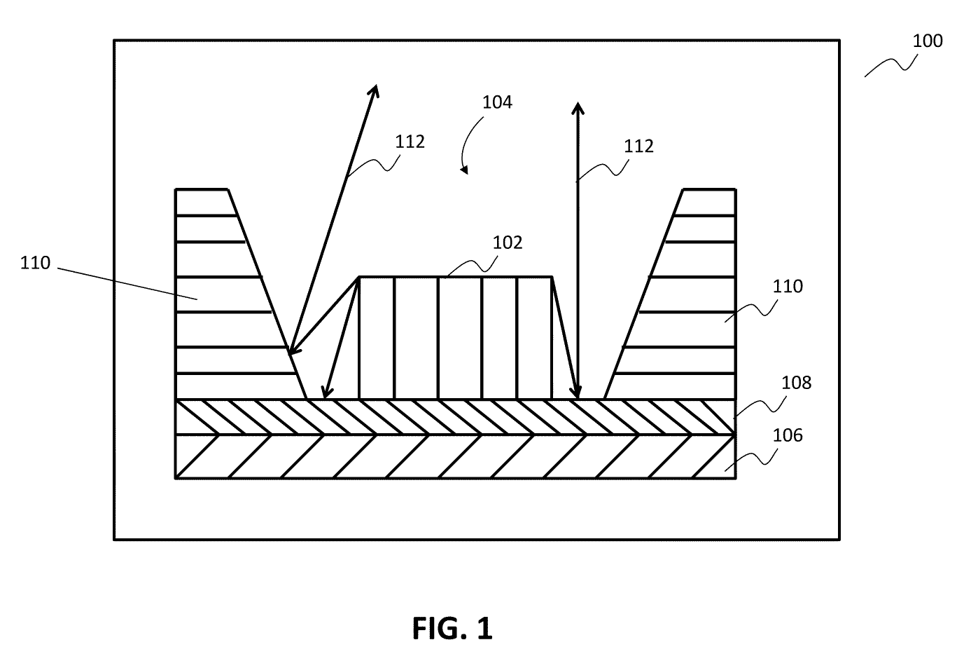

FIG. 1 shows one particular suitable use of a reflective coating prepared according to the present teachings and applied on a chip-on-board (COB) light emitting diode (LED) package 100. In various embodiments, an LED package thin film coated reflector with a metal substrate is provided. The thin film reflector may include a multilayer thin film deposited on the underlying metal substrate. Thus, in various embodiments, the LED package 100 includes a multilayer thin film coated reflector mounted on a metal substrate, which improves reflectivity and angular distribution of the luminance and is impervious to humidity, oxidation and sulfide tarnish.

FIG. 1 is an illustration of a cross-sectional view of an LED package 100 having an LED chip (or semiconductor die) 102, which acts as light source and radiates light from the LED chip when electrically activated. The LED chip 102 is positioned within a recessed cavity 104 formed as a concave region, as shown in the exemplary embodiment in FIG. 1. In various embodiments, the LED chip 102 is electrically connected to a thin film reflective layer 108 without using lead wires. In other embodiments, the LED chip 12 is electrically connected to the thin film reflective layer 108 using lead wires. Layer 108 represents a reflector. The formation of the thin film reflective layer 108 will be described in details below.

In an embodiment, the LED package 100 can include an electrical interconnect layer, thin film layer, and a metal substrate. The thin film layer is mounted above the metal substrate. The thin film layer can include a dielectric layer having a thickness about several micrometer. The electrical interconnect layer can be configured as an additional layer positioned on top of the thin film layer. Namely, the metal substrate can function as a mechanical holder and a heat sink. The thin film can function as a dielectric and a reflective layer. The interconnect layer may include openings to electrically isolate portions of the layer from one another or facilitate electrical connections to other portion of the device.

In various embodiments, a masking technique may be applied to the device. Certain reflective thin film coatings are typically electrically insulating as they are preferably comprised of alternating layers of dielectric metal oxides. In some embodiments, it may be preferred to leave one or more predetermined areas of the lead frame substrate uncoated, for example, to allow electrical contact from the LED die to conductive traces. One such method of masking is described in U.S. Pat. Nos. 5,676,579 and 5,587,626. A preferred method of masking certain areas of a substrate that is coated in a CVD or PVD process can be implemented through the use of boric oxide (B₂O₃) via direct application. An alternative method is through the application of a B₂O₃ precursor and subsequent conversion to B₂O₃. The boric oxide or other masking material can be applied to the desired areas of the lead frame, e.g. conductive bonding pads. The masking material can be removed after the deposition of the thin film reflective coating, exposing the desired areas of the lead frame, e.g. for attachment of an LED chip to the conductive bonding pads.

In reference to FIG. 1, a pair of sidewalls 110 are connected to the reflective layer 108. In some embodiments, sidewalls 110 can function as a reflector for light emitted from the LED chip 102. The sidewalls 110 may be made of plastic and coated with a reflective material having a high reflectivity. In various embodiments, the structure of the sidewalls 110 is made of plastic and functions as a reflector having excellent mechanical properties.

As shown in FIG. 1, the thin film reflective layer 108 is mounted on a metal substrate 106 or base layer such that the reflective layer 108 coats the metal substrate 106. Layer 106 represents a mechanical, thermal, and electrical substrate. Namely, the LED package performance relates to parameters such as thermal performance, electrical performance and mechanical performance. Thus, the metal substrate 106 can be produced from any metal material or combination of materials to reach the desired level of mechanical, thermal and electrical performance.

In the preferred embodiments, the metal substrate 106 is a highly conductive metal. The metal substrate 106 is typically formed of, for example, aluminum, copper, steel, or die-cast alloys.

In various exemplary embodiments, metal substrate 106, which in some embodiments can be a highly semi-conductive material, such as, for example, aluminum, can be formed having a particular surface roughness.

In some embodiments, a coating may be applied to the surface of the roughened metal substrate to provide a smooth surface. The coating may be applied between the thin film reflective coating 108 and the metal substrate 106. The smoothing technology employed to smooth the surface of the metal substrate may include, for example, anodizing, chemically etching, or other plating technology coating overlaying a metal substrate. In one example, anodized technology can be used to smooth the surface of an aluminum-metal substrate. In another example, metal plating can be used to smooth the surface of a copper-metal substrate. As further examples, porcelain or sol-gel can also be used to smooth the surface of the metal substrate.

FIG. 1 is a simplified cross-sectional view of an LED package 100. This diagram is merely an example that should not limit the scope of the present teachings and claims. One of ordinary skill in the art would recognize many variations, alternatives, and modifications. For example, the light reflectors may be formed in various shapes and profiles including circular, rectangular, octagonal, etc.

In various embodiments, an LED package can include numerous LED chips (or dice) prepared according to the present teachings. The LED package can be configured as a multi-chip packaged LED light source. The light source can be a COB LED which has closely packed multiple LED dice that appear as a single lighting module when illuminated.

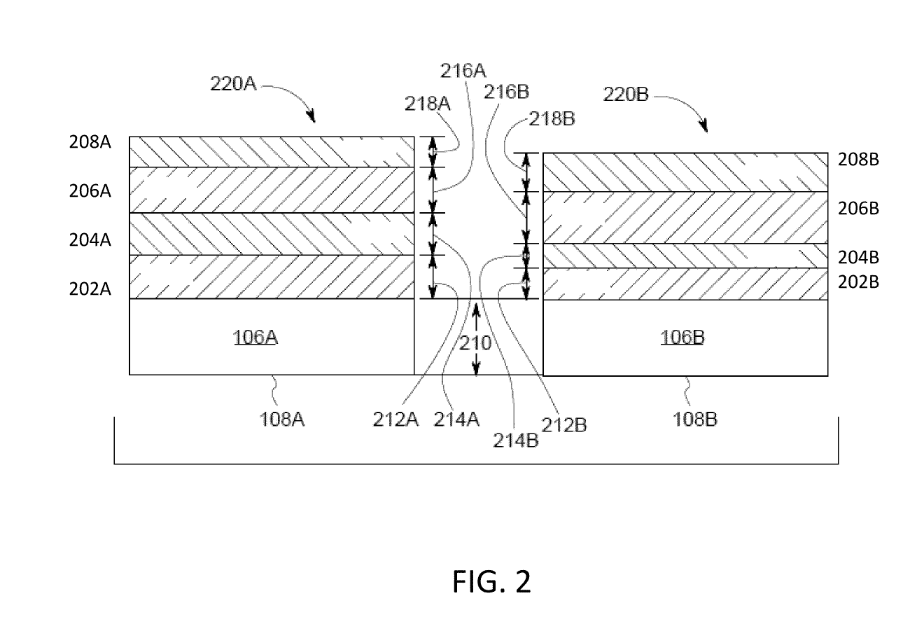

FIG. 2 depicts an exemplary embodiment of multiple reflectors 108A, 108B mounted within an LED package containing multiple LED chips (not shown in FIG. 2) prepared according to the description of FIG. 1. FIG. 2 illustrates two reflectors 108A, 108B mounted on substrates 106A, 106B attached to a lead frame (not shown). Reflectors 108A, 108B includes LED chip mounting areas on their top surface for seating an LED chip (as shown in FIG. 1).

In FIG. 2, the exemplary reflectors 108A, 108B can be constructed to utilize the reflective coating formed according to the presently described methods. FIG. 2 shows partial cross sections of the two example reflectors 108A, 108B of a lighting system, such as an LED package. In the example shown in FIG. 2, the lighting system illustrated can be referred to as a multi-reflector system, having multiple reflectors 108A, 108B. While two reflectors 108A, 108B are shown, the lighting system in various embodiments includes any number of distinct reflectors, whether any of the reflectors are connected directly to each other.

The system in other embodiments (as shown in FIG. 1) can include a single reflector component 108. However, and while multiple reflectors 108A, 108B are shown schematically as separate components, two or more of the reflectors 108A, 108B are in some embodiments connected to each other, e.g., directly. The combined reflector of such embodiments, including, e.g., each illustrated reflector component 108A, 108B of FIG. 2, may share a common substrate or have connecting substrates, for instance.

Each reflector 108A, 108B includes a substrate, or base reflector surface 106A, 106B. The base reflector surfaces 106A, 106B may include any of a variety of materials. In various embodiments, the substrate comprises a metal substrate. In one embodiment, one or both base surfaces 106A, 106B are non-reflective or minimally reflective. In one embodiment, one or both base surfaces 106A, 106B are reflective.

In the preferred embodiments, one or both base surfaces 106A, 106B is a metal substrate made of a highly conductive metal. The metal substrate 106 is typically formed of, for example, aluminum, copper, steel, or die-cast alloys.

In various exemplary embodiments, metal substrate 106, 106A, 106B can be formed having a rough surface structure. The metal substrate 106, 106A, 106B can be fabricated such that the entire surface is completely roughened or a portion of the surface is roughened. The rough surface can be formed for reflecting emitted light so as to improve the reflectivity. Thus, the high reflectivity of the substrate is dependent upon the roughness and not the substrate material. For example, the metal substrate can be fabricated having a surface roughness between 2000 nm and 200 nm.

In some embodiments, a coating (not shown) may be deposited on the surface of the roughened metal substrate to provide a smooth surface. The coating may be applied below the thin film and above the metal substrate. For example in FIG. 2, the coating may be applied between layer 202A, 202B of the thin film reflective coating and the metal substrate 106A, 106B. The smoothing technology employed to smooth the surface of the metal substrate may include, for example, anodizing, chemically etching, or other plating technology coating overlaying a metal substrate. In one example, anodized technology can be used to smooth the surface of an aluminum-metal substrate. In another example, metal plating can be used to smooth the surface of a copper-metal substrate. For example, the smoothing layer can have a surface roughness between 200 nm and 20 nm.

Referring back to reflectors 108, 108A, 108B as shown in FIGS. 1 and 2, in comparison to conventional reflectors of a COB type package, conventional reflectors are typically formed of silver (Ag). Silver is easy to apply, inexpensive, and highly reflective. However, silver has a tendancy to corrode (e.g. turns black) and peel off. In COB applications, it is also necessary to utilize an organic based top coating to protect silver from oxidation due to humidity, oxygen dioxide, and outgas produced due to phosphors and the environment. The present invention replaces silver with a very robust thin film coating 108, 108A, 108B described below. Some of the advantages of using reflective layer 108, 108A, 108B include, for example, improved reflectivity (at approximately 97%); higher temperature reliability up to 400° C.; spectrally tunable in comparison to silver; impervious to humidity, oxidation and sulfide tarnish; friendly to low cost red sulfide phosphors; and a decrease in the cost of metal base lead frame and COB substrates.

In the reflectors 108A, 108B shown in FIG. 2, each thin-film reflective stack 220A, 220B includes multiple layers positioned directly adjacent (i.e., directly atop, in the view of FIG. 2) the reflector base 106A, 106B. In embodiments of the present technology, two or more of the reflectors 108A, 108B are coated with distinct multilayer thin-film reflective stacks 220A, 220B. Each stack 220A, 220B can include distinct types of layered reflectors e.g., dielectric mirrors, Bragg reflectors, or dichroic mirrors. The stacks 220A, 220B in these embodiments include multiple relatively thin stacked layers or films of, e.g., dielectric material.

Various characteristics or factors define each stack 220A, 220B. Characteristics include a number, size (e.g., thickness), shape, and material of stack layers. One or more of the characteristics are, according to the present technology, a function of lighting system geometry and optics.

The system geometry factors can include a configuration (e.g., size and shape) and arrangement (e.g., positioning and orientation) of the reflectors 108A, 108B in the system.

The optical factors can include at least those resulting from the system geometry, such as the incident angles of light on the light stack 220A, 220B. The optical factors can also include color presence or distribution (e.g., wavelength range, or median wavelength, etc.) of the light to arrive at the stacks.

While each stack 220A, 220B is shown to include four layers each, for illustrative purposes, the stacks can include any desired number of layers. The number of layers can be even or odd. The number in some embodiments, is greater than four e.g., five layers, ten layers, fifteen layers, twenty layers, numbers between these, or greater than these. In a preferred embodiment, at least one of stack 220A, 220B includes twenty-six (26) layers.

The layers can include any of a variety of materials. In some embodiments, each layer consists preferably of a dielectric material. In some embodiments, each stack 220A, 220B includes at least two different material layers, such as two different dielectric materials. The layers can vary by their characteristic of refractive index. In a contemplated embodiment, at least one of the layers is a non-dielectric.

In one embodiment, the layers of each stack 220A, 220B include alternating layers of a first material (e.g., first dielectric material) having a relatively high refractive index and a second material (e.g., second dielectric material) having a relatively low refractive index. In this alternating arrangement, each relatively high refractive index material can be the same, and each relatively low refractive index material can be the exact same, but that need not be the case in every implementation.

For some implementations, it is preferred that the number of layers be even (e.g. 26 layers). In other embodiments, the number of layers may be odd. In at least one of those implementations, it is preferred that the final layer (e.g., top layer) also include a relatively high refractive index film.

The refractive index (n) of a material is the ratio of the speed of light in vacuum (c) and the speed of light within the material (v), or n=c/v. While the materials used in an dielectric stack may have other refractive indexes, in one of the embodiments having an alternating high-index/low-index arrangement, relatively high refractive indexes are between about n=2.2 and about n=2.6 nm—e.g., about n=2.4, and relatively low refractive indexes are between about n=1.2 and about n=1.8—e.g., about n=1.5.

Continuing with the example of FIG. 2, the stacks 220A, 220B begin with a low, or least relatively low, refractive index layer 202A, 202B positioned directly adjacent, and contacting directly, the substrates 106A, 106B, respectively. According to the alternating arrangement, the next layers 204A, 204B thus have a high, or relatively high, refractive index.

The final two layers illustrated are, then, continuing with the alternating arrangement, low refractive index layers 206A, B and high refractive index layers 208A, B.

The layers 202A/B, 204A/B, 206A/B, 208A/B of the stacks 220A, 220B can also be set to any of a wide variety of thicknesses. In FIG. 2, a thickness of the substrate 106A, 106B is identified by reference numeral 210. Thicknesses of the layers 202A/B, 204A/B, 206A/B, 208A/B are referenced by numerals 212A/B, 214A/B, 216A/B, and 218A/B, respectively.

Layer thicknesses for each implementation can be represented by, e.g., a linear measure, such as nanometers (nm) or millimeters (mm). In one embodiment, each layer 202A/B, 204A/B, 206A/B, 208A/B of the stacks 220A, 220B has a thickness of between about 100 nm and about 200 nm. The substrate, or base surface 106A, 106B, and any superstrate are in some cases much thicker. In one embodiment, for example, the substrate has a thickness between about 400 nm and about 600 nm e.g., about 500 nm. Any superstrate can be of similar thickness.

In an embodiment, the thin-film coating of stacks 220A, 220B can be formed of any highly smooth and low average roughness (Ra), and high temperature stable base layer 106A, 106B. As understood by those of skill in the art, the multi-layer thin-film coating can be composed of alternating high- and low-refractive index layers to reflect and refract light. The layer thicknesses are chosen in such a manner as to generate constructive interference for desired wavelengths of light, most often by creating Quarter Wave Stacks (QWS). A QWS is the most efficient way to reflect light at a given wavelength, as the optical thickness of the layer is ¼ the wavelength of the light which then generates constructive interference upon reflection of the light at the layer interfaces.

For example, the LED lead frame reflectors can be made from copper metal coated with an aluminum thin-film twenty-six (26) layered constructive interference metal oxide dielectric coatings. In such an exemplary embodiment, the enhanced aluminum thin film has a broader high reflectivity range from 380 nm to 780 nm in comparison to silver (Ag), especially coated with organic coatings.

Thus, various embodiments combine a twenty-six (26) layer enhanced aluminum thin film chemical vapor deposition (CVD) coating processes (such as GE Lighting's proprietary ALGLAS coating) with LED lead frame and COB reflectors. The designed constructive interference thin film can be produced either through a CVD coating process for high temperature stable glass, ceramic and metal, etc. or a physical vapor deposition (PVD) coating process for a low temperature stable plastic. These are merely examples of a process of preparing the coating. Other known processes or proprietary processes can be utilized to produce the coating on the reflector(s).

More particularly, the thickness for one or more of the layers of each reflector component in FIGS. 1 and 2 can be pre-selected based on an expected angle or angles (or angle range) of incidence at which light from the source (such as lamp 102 in FIG. 1) will impinge on the stack 220A, 220B.

Multipart reflector assemblies may encounter incident light such as light rays 112 from varying angles from the light source(s) 102. In FIGS. 1 and 2, the LED package is configured as a multipart reflector assembly wherein multiple elements comprise a reflective component, such as a reflective layer and/or reflective coating. In the example of FIGS. 1 and 2, a light reflector is coated on sidewalls 110 and is provided within the recessed cavity 104 through the use of reflective layer 108.

In FIG. 1, reflectors (reflective layer 108 and sidewalls 110) receive various light rays 112 and reflect these light rays at an angle of incidence. This can result in multiple light rays arriving at the reflectors within a range of incidence angles. As described above, some conventional lighting systems are designed so that some reflectors, or portions of a reflector, receive light arriving within the optimal range of incident angles. Other conventional reflectors or portions receive light at angles outside of the optimal range. Incident angles outside of the optimal angles can approach 0° on the low end and 90° on the other. Rays arriving outside of the optimal range reflect with an undesirable shift in color, and less-than-desirable intensity.

Therefore, during operation according to the present teachings, the light 112 output direction faces the cavity opening 104 of the package LED 100. The sidewalls 110 gradually expands toward the lighting opening to form inclined sidewalls. The angle of the inclined sidewalls can be chose to ensure that the light 112 will emit via the lighting opening after multiple internal reflections. Thus, in various embodiments, the angle of inclination of the sidewalls can be selected based on the desired profile of the light emitted from the LED chip 102.

When the LED chip 102 emits light via the light opening of the cavity 104, a portion of indirectly emitted light may impinge sidewalls 110 and reflective layer 108. The high reflectivity of the reflective layer 108 and sidewalls 110, as prepared according to the present teachings, enables the incident angle of these reflecting light rays to be predicted and better controlled. Namely, the thickness of one or more of the layers of each reflector component can be pre-selected based on an expected angle or angles (or angle range) of incidence. In one example, the reflector(s) may be configured to have over a 95% reflectance at a nominal incident angle. The thin film structure can be optimized at incident angles within a range of from 15°-75°, depending upon the stack configuration.

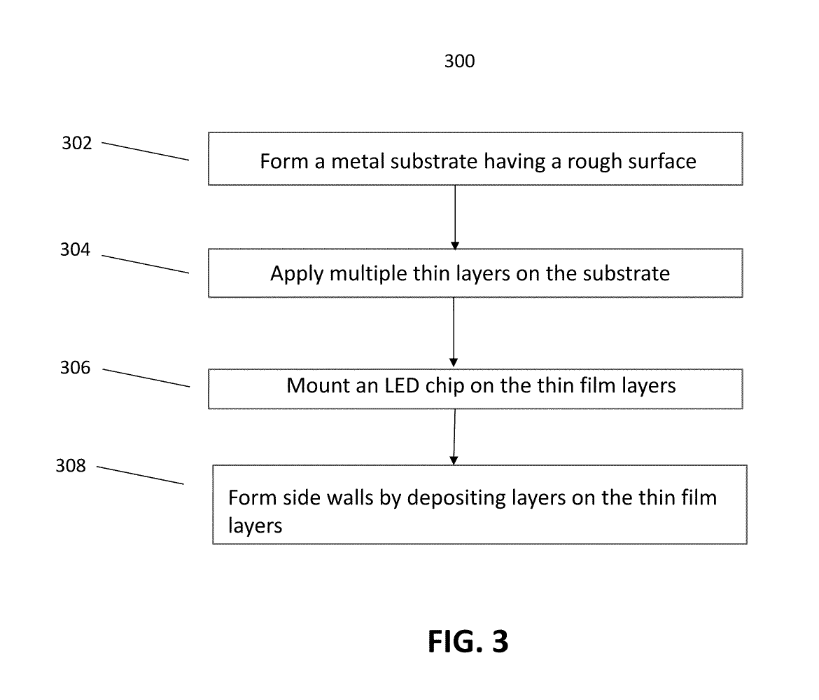

FIG. 3 is a flowchart explaining a method 300 for manufacturing an LED package according to the present teachings. In Step 302, a metal substrate having a rough surface is formed. Optionally, a smoothing coating may be deposited onto the metal substrate to provide a smooth surface. In Step 304, multiple thin layers are applied on the substrate to form a thin film. In Step 306, one or more LED chips (or dice) could be mounted above the substrate, for example, on the thin film or on metal conducting layer(s). In Step 308, sidewalls are formed by depositing layers on the thin film to form a cavity around the area wherein the LED chip(s) is disposed therein.

Thus, the present disclosure most generally concerns an LED package with reflectors designed for improved reflectivity. According to various embodiments, provided are multilayer dielectric coatings for LED lead frame and COB substrate reflector with a reflectance over 95% at a nominal incident angle. In various embodiments, the substrate is a metal substrate. More particularly, the substrate is a thermally conductive metal substrate. The material of the substrate can be selected, for example, from the group consisting of aluminum, copper, steel, and any metal alloy combination with a thermal conductivity over 10 W/mK.

For further details regarding suitable thin films and methods of preparing such thin films that can be integrated or incorporated within the LED package, reference may be made to the disclosure in detail in GE Attorney Docket No. 270999 entitled Reflecting Apparatus Including Tuned Optical Coatings and Methods for Making The Same, which is hereby incorporated by reference in its entirety.

Alternative embodiments, examples, and modifications which would still be encompassed by the invention may be made by those skilled in the art, particularly in light of the foregoing teachings. Further, it should be understood that the terminology used to describe the invention is intended to be in the nature of words of description rather than of limitation.

Those skilled in the art will also appreciate that various adaptations and modifications of the preferred and alternative embodiments described above can be configured without departing from the scope and spirit of the invention. Therefore, it is to be understood that, within the scope of the appended claims, the invention may be practiced other than as specifically described herein.

1. A light emitting diode (LED) package, comprising:
a metal substrate;
a multilayer reflector disposed on at least a portion of the metal substrate, the multilayer reflector comprising at least two different metal oxide dielectric layers with different refractive index; and
at least one light emitting diode (LED) chip mounted above at least a portion of the metal substrate.

2. The package of claim 1, wherein the multilayer reflector is applied between the at least one LED chip and the metal substrate.

3. The package of claim 1, wherein the LED chip is attached directly to at least a portion of the metal substrate.

4. The package of claim 1, wherein the metal substrate comprises a highly conductive metal.

5. The package of claim 4, wherein the metal includes at least one selected from a group consisting of aluminum, copper, steel, and metal alloy combinations.

6. The package of claim 1, wherein a coating is applied to at least a portion of the metal substrate to smooth a surface of the metal substrate, prior to applying the multilayer reflector.

7. The package of claim 6, wherein the coating is formed from a smoothing process selected from anodization, chemical etching, electroplating, and other surface plating technologies.

8. (canceled)

9. (canceled)

10. The package of claim 1, wherein the multilayer reflector comprises is a multilayer stack designed to generate constructive interference of visible light.

11. The package of claim 1, wherein the multilayer reflector comprises a reflective coating having over a 95% reflectance at a nominal incident angle.

12. The package of claim 1, further comprising a multi-chip LED light source.

13. A method for producing a light emitting diode (LED) package, comprising:
applying a multilayer reflector to at least a portion of a metal substrate, wherein the multilayer reflector comprising at least two different metal oxide dielectric layers with different refractive index; and
mounting at least one light emitting diode (LED) chip above at least a portion of the metal substrate.

14. The method of claim 13, further comprising applying the multilayer reflector between the at least one LED chip and the metal substrate.

15. The method of claim 13, further comprising attaching the LED chip directly to at least a portion of the metal substrate.

16. The method of claim 13, wherein the metal substrate comprises a highly conductive metal.

17. The method of claim 16, wherein the metal includes at least one selected from a group consisting of aluminum, copper, steel, and metal alloy combinations.

18. The method of claim 13, further comprising applying a coating to at least a portion of the metal substrate to smooth a surface of the metal substrate, prior to applying the multilayer reflector.

19. (canceled)

20. (canceled)

21. The package of claim 1, wherein the multilayer reflector comprises a quarter-wave stack.

22. The package of claim 1, wherein the multilayer reflector comprises dielectric mirror, Bragg reflector, or dichroic mirror.

23. The package of claim 9, wherein the multilayer reflector further comprises a non-dielectric layer.
